(19) United States
(12) Patent Application Publication
(10) Pub. No.: US 2026/0035835 A1
(43) Pub. Date: Feb. 5, 2026

(54) METHODS FOR SELECTIVELY DEPOSITING A BORON DOPED SILICON GERMANIUM LAYER ON A SURFACE OF A SUBSTRATE

(71) Applicant: ASM IP Holding B.V., Almere (NL)

(72) Inventors: Daniel Casey, Herent (BE); Rami Khazaka, Leuven (BE); Patricio Eduardo Romero, Boutersem (BE)

(21) Appl. No.: 19/281,879

(22) Filed: Jul. 28, 2025

Related U.S. Application Data
(60) Provisional application No. 63/677,896, filed on Jul. 31, 2024.

(51) Int. Cl. C30B 31/08; C30B 25/04; C30B 29/06; C30B 29/08; C30B 31/18

(52) U.S. Cl. CPC C30B 31/08; C30B 25/04; C30B 29/06; C30B 29/08; C30B 31/185

(57) ABSTRACT

Methods for selectively depositing a boron doped silicon germanium layer on a substrate disposed within a reaction chamber are disclosed. The methods disclosed include selectively depositing the boron doped silicon germanium layers by an epitaxial deposition process employing a silicon precursor, a germanium halide precursor, and a boron halide dopant precursor.

### CROSS-REFERENCE TO RELATED APPLICATION(S)

This application claims the benefit of U.S. Provisional Application 63/677,896 filed on Jul. 31, 2024, the entire contents of which are incorporated herein by reference.

### FIELD

The present disclosure relates generally to the field of semiconductor processing methods, and associated structures, and to the field of device and integrated circuit manufacture. In particular, the present the disclosure generally relates to methods for selectively depositing boron doped silicon germanium layers.

### BACKGROUND

Silicon germanium (SiGe) layers are increasingly employed in semiconductor devices due in part to such high mobility layers improving device performance, speed, power consumption, and breakdown fields compared to similar devices fabrication with lower mobility semiconductors, such as silicon, for example.

A variety of deposition processes can be utilized for the deposition of silicon germanium layers, including chemical vapor deposition, molecular beam epitaxy, and physical vapor deposition, for example. In particular, epitaxial deposition processes can be used to deposit monocrystalline silicon germanium layers. The deposition of silicon germanium layers can also include doping the layers with select impurities to improve/control the layers electrical characteristics. For example, SiGe layers can be doped p-type by the incorporation of boron into the SiGe layer.

However, improvements in deposition methods used for depositing silicon germanium layers are needed to maintain or even improve device/integrated circuit performance as device density increases and substrate real estate decreases. Accordingly, improved deposition methods are desirable for enabling the deposition of enhanced silicon germanium layers.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods for selectively depositing boron doped silicon germanium layers. As set forth in more detail below, the methods provided can enable the selective deposition of boron doped silicon germanium layers having both a high active dopant concentration and a high germanium content.

In accordance with examples of the disclosure a method of selectively depositing a boron doped silicon germanium layer on a substrate disposed within a reaction chamber is provided, the method comprising: heating the substrate to a deposition temperature; and depositing the boron doped silicon germanium layer on a surface of the substrate by a selective epitaxial deposition process comprising: introducing a silicon precursor into the reaction chamber, the silicon precursor having a general formula of the form SiₙXₘH₂ₙ₊₂₋ₘ, with X being selected from Cl, Br, and I, with n being an integer from at least 2 to at most 4, and with m being an integer from at least 1 to at most 2n+2−m; introducing a germanium halide precursor into the reaction chamber; and introducing a boron halide dopant precursor into the reaction chamber, the boron halide dopant precursor having a general formula of the form BₚY_{q}H_{3p-q}, with Y being selected from Cl, Br, and I, with p being an integer from at least 1, and q being an integer from at least 1 to at most 3p.

In some embodiments the silicon precursor, the germanium halide precursor, and the boron halide dopant precursor are co-flowed into the reaction chamber.

In some embodiments the deposition temperature is between 250° C. and 450° C.

In some embodiments the silicon precursor comprises a chlorosilane precursor selected from a group consisting of Si₂Cl₅H, Si₂ClH₅, Si₂Cl₂H₄, and Si₃Cl₈. In some embodiments the chlorosilane precursor comprises Si₂Cl₅H.

In some embodiments the germanium halide precursor comprises a germanium chloride precursor. In some embodiments the germanium chloride precursor comprises at least one of GeCl₃H, GeCl₄, GeClH₃, GeCl₂H₂, and Ge₂ClH₅.

In some embodiments the boron halide dopant precursor comprises at least one of BH₂Cl, BCl₂H, BCl₃, and BBr₃.

In some embodiments the selective epitaxial deposition process preferentially deposits the boron doped silicon germanium layer on a surface A relative to a surface B, wherein the surface A is a silicon surface, and the surface B is a silicon oxide surface or a silicon nitride surface.

In some embodiments the method further comprising introducing an etchant into the reaction chamber.

In accordance with additional examples of the disclosure a method of forming a boron doped silicon germanium layer on a substrate is provided, the method comprising: heating the substrate to a deposition temperature 250° C. and 450° C.; and contacting the substrate with a precursor gas composition, the precursor gas composition comprising: a silicon precursor having a general formula of the form SiₙClₘH₂ₙ₊₂₋ₘ, with n being an integer from at least 2 to at most 4, and with m being an integer from at least 1 to at most 2n+2−m; a germanium halide precursor comprising one or more of GeCl₃H, GeCl₄, GeClH₃, GeCl₂H₂, and Ge₂ClH₅; and a boron halide dopant precursor comprising one or more of BCl₃ and BBr₃.

In some embodiments the precursor gas composition consists essentially of the silicon precursor, the germanium halide precursor, and the boron halide dopant precursor.

In some embodiments the silicon precursor comprises one or more of Si₂Cl₅H, Si₂ClH₅, Si₂Cl₂H₄, and Si₃Cl₈.

In some embodiments the boron doped silicon germanium layer is formed by a selective epitaxial deposition process which preferentially deposits the boron doped silicon germanium layer on a surface A relative to a surface B, wherein the surface A is a silicon surface, and the surface B is a silicon oxide surface or a silicon nitride surface.

In some embodiments the precursor gas composition further comprises an additional germanium precursor selected from a group consisting of GeH₄, Ge₂H₆, Ge₃H₈, GeH₆Si, GeCl₄, GeCl₂, and GeCl₂H₂.

In some embodiments the precursor gas composition further comprises an additional silicon precursor selected from a group consisting of silanes, chlorosilanes, and iodosilanes.

In some embodiments the precursor gas composition further comprises an additional boron precursor selected from a group consisting of B₂H₆, B₂D₆, BH₂Cl, BCl₂H, BCl₃, and BBr₃.

In accordance with further examples of the disclosure a method of forming a contact layer to a silicon germanium source/drain region is provided, the method comprising: seating a substrate within a reaction chamber, the substrate comprising one or more silicon germanium source/drain regions; heating the substrate to a deposition temperature between 250° C. and 450° C.; and depositing a boron doped silicon germanium layer directly on a surface of the silicon germanium source/drain region by a selective epitaxial deposition process by co-flowing into the reaction chamber a precursor gas composition comprising: a silicon precursor having a general formula of the form SiₙXₘH₂ₙ₊₂₋ₘ, with X being selected from Cl, Br, and I, with n being an integer from at least 2 to at most 4, and with m being an integer from at least 1 to at most 2n+2−m; a germanium halide precursor; and a boron halide dopant precursor having a general formula of the form BₚY_{q}H_{3p-q}, with Y being selected from Cl, Br, and I, with p being an integer from at least 1, and q being an integer from at least 1 to at most 3p.

In some embodiments the selective epitaxial deposition process preferentially deposits the boron doped silicon germanium layer on the surface of the silicon germanium source/drain region relative to a silicon oxide surface or a silicon nitride surface.

In some embodiments the deposited boron doped silicon germanium layer has both an active dopant concentration greater than 3×10²¹ cm⁻³ and a germanium content greater than 50 atomic percent (atomic-%).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a method for selectively depositing a boron doped silicon germanium layers in accordance with one or more embodiments of the disclosure.

FIGS. 2-5 illustrates structures formed by methods provided in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group Ill-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gases include noble gasses, nitrogen, and the like. In some cases, the term “precursor” can refer to a compound that participates in the chemical reaction that produces another compound, and particularly to a compound that constitutes a film matrix or a main skeleton of a film. In addition, the term “reactant” can be used interchangeably with the term “precursor.”

As used herein, the term “epitaxial layer” can refer to a substantially single crystalline layer directly on an underlying substantially single crystalline substrate or layer.

As used herein, the term “chemical vapor deposition” can refer to any process wherein a substrate is exposed to one or more volatile precursors (as well as optional additional process gases), which react and/or decompose on a substrate surface to produce a desired deposition.

As used here, the term “silicon germanium” can refer to a semiconductor material comprising silicon and germanium and can be represented as Si₁₋ₓGeₓ wherein 1≥x≥0, or 0.8≥x≥0.1, or 0.6≥x≥0.2, or materials comprising silicon and germanium having compositions as set forth herein. In addition, the term “silicon germanium” can be represented as SiGe and can further be represented as SiGe:B when said silicon germanium is doped with a boron dopant. Likewise, a silicon material doped with a boron dopant can be represented as Si:B.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying”, or “below” will be construed to be relative concepts.

Various embodiments of the present disclosure relate to methods for selectively depositing boron doped silicon germanium layers (SiGe:B). As set forth in more detail below, the methods provided can enable the selective epitaxial deposition of SiGe:B layers having both a high active dopant concentration and a high germanium content. The epitaxial deposition processes of the present disclosure can employ a precursor gas composition (e.g., a deposition gas composition) comprising a silicon precursor, a germanium halide precursor, and a boron halide dopant precursor. The selective epitaxial deposition processes can preferentially deposit a boron doped silicon germanium layer on a first surface (surface A) relative to a second surface (surface B). In some examples, the selective epitaxial deposition processes can further include the introduction of an etchant gas.

As device density increases in integrated circuits (e.g., logic device and circuits), the area between the source/drain regions of the transistors and the metal interconnect layers (e.g., middle-of-the-line) continues to shrink. This reduction in area for interconnecting devices can limit device performance as the contact resistivity (pc) becomes increasing dominant. Therefore, the embodiments of the present disclosure also provide methods to reduce contact resistivity (pc) by enabling the depositing of boron doped silicon germanium layers with both a high active dopant concentration and a high germanium content. In such embodiments, the contact resistivity (pc) can be reduced by raising the active doping concentration in the source/drain regions. Further, in such examples, the contact resistivity (pc) can be reduced by decreasing the Schottky Barrier Height (SBH) between source/drain regions and a metal of the interconnecting layer.

In more detail, and in accordance with examples of the disclosure, a thin contact layer comprising a boron doped silicon germanium layer can be deposited on the source/drain regions of the transistor structures. In such examples, the thin contact layer comprises SiGe:B layers of the present disclosure (i.e., with both high germanium and active dopant concentrations). Further in such examples, the contact layer can be kept thin and as such the lattice mismatch between the contact layer and the underlying layers can be better controlled thereby maintaining the strain across the contact layer without the formation (or with a reduced formation) of defects, such as misfit dislocations, for example. In addition, the high active dopant concentration in the SiGe:B layers of the disclosure can assist in compensating strain induced by the high germanium content in the SiGe:B layers.

Common deposition methods are unable to successfully obtain both the high active donor concentrations and germanium content enable by the methods provided. For example, common methods for the deposition of SiGe:B layers often result in a plateau and eventually a reduction in active dopant concentration as the germanium content is increased in the SiGe:B layer.

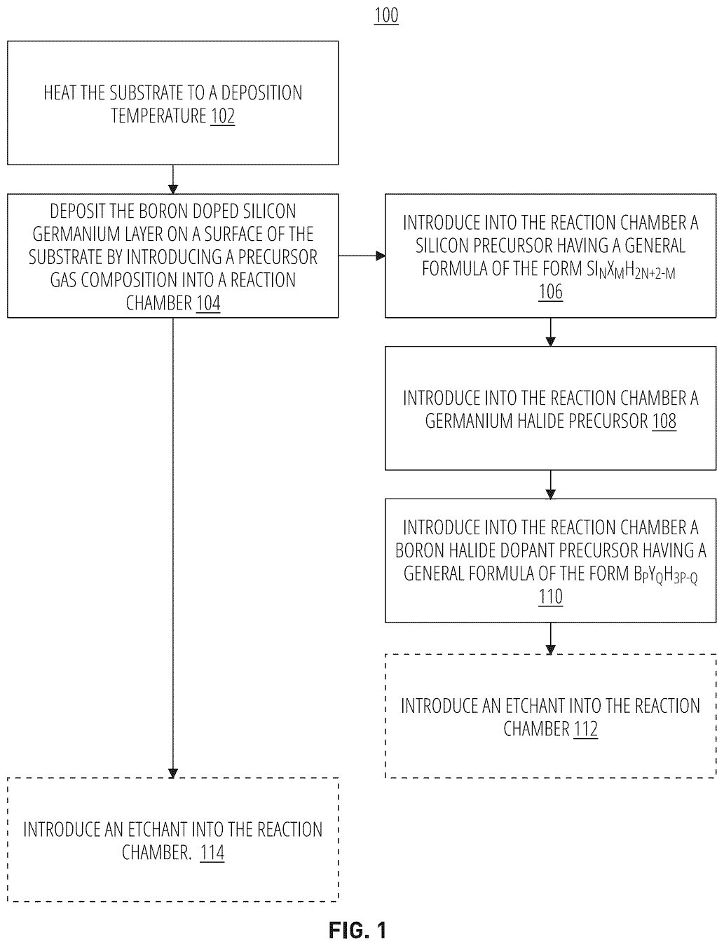

Turning now to the figures, FIG. 1 illustrates a method 100 for selectively depositing a boron doped silicon germanium layer on a substrate. Briefly, method 100 includes the steps of, seating a substrate within a reaction chamber and heating the substrate to a deposition temperature (step 102). Method 100 can further comprise depositing a boron doped silicon germanium layer on a surface of the substrate (step 104) by introducing a precursor gas composition into the reaction chamber. In such examples introducing the precursor gas composition can comprise the sub-steps of: introducing a silicon precursor (sub-step 106), introducing a germanium halide precursor (sub-step 108), and introducing a boron halide dopant precursor (sub-step 110). In some embodiments method 100 may also comprises introducing an etchant gas into reaction chamber (optional sub-step 112) during the deposition of the boron doped silicon germanium layer and/or introducing an etchant gas into the reaction chamber (optional step 114) upon completion of the deposition of the boron doped silicon germanium layer.

In accordance with examples of the disclosure, step 102 of method 100 comprises seating the substrate in a reaction chamber and heating the substrate to a deposition temperature (i.e., a substrate temperature). In such examples the reaction chamber may comprise a reaction chamber of a chemical vapor deposition system. However, it is also contemplated that other reaction chambers (such as, for example, atomic layer deposition reaction chambers) and alternative chemical vapor deposition systems may also be utilized to perform the embodiments of the present disclosure. In some embodiments, the reaction chamber is configured for performing epitaxial deposition processes. In some embodiments, the reaction chamber may form part of a cluster-type semiconductor processing system, which can include multiple process modules for performing various semiconductor processing operations. In such embodiments the cluster-type semiconductor processing system can include two or more reaction chambers configured to perform the epitaxial deposition processes of the present disclosure.

In accordance with examples of the disclosure, step 102 can comprise heating the substrate to a deposition temperature less than 500° C., less than 450° C., less than 400° C., less than 350° C., less than 300° C., less than 250° C., or less than 200° C. In some embodiments the deposition temperature is between 200° C. and 500° C., between 250° C. and 450° C., between 200° C. and 400° C., between 250° C. and 400° C., or between 250° C. and 300° C.

In addition to controlling the temperature of the substrate during deposition, the pressure within the reaction chamber can also be regulated. For example, the pressure within the reaction chamber during deposition can be less than 760 Torr, less than 350 Torr, less than 100 Torr, less than 50 Torr, less than 25 Torr, less than 10 Torr, or less than 5 Torr. In some embodiments, the pressure in the chamber body during deposition is between 5 Torr and 760 Torr, or between 10 Torr and 60 Torr, or between 20 Torr and 40 Torr.

In accordance with examples of the disclosure, method 100 can further comprise the step of depositing a boron doped silicon germanium layer on a surface of the substrate by introducing a precursor gas composition into the reaction chamber (step 104). In such examples the deposition process can comprise a thermal deposition process which is performed within the reaction chamber without the use of excited species generated from a plasma, i.e., the deposition process is a thermal deposition process performed in a plasma-free environment. In some embodiments the deposition process is a chemical vapor deposition (CVD) process. In various embodiments the chemical vapor deposition process is an epitaxial deposition process, such as, a selective epitaxial deposition process, for example.

In accordance with examples of the disclosure, depositing the boron doped silicon germanium layer on the surface of the substrate by introducing a precursor gas composition into the reaction chamber (step 104) can further comprise the sub-steps of: introducing a silicon precursor into the reaction chamber (sub-step 106), introducing a germanium halide precursor into the reaction chamber (sub-step 108), and introducing a boron halide dopant precursor into the reaction chamber (sub-step 110). In further examples depositing the boron doped silicon germanium layer (e.g., step 104 and the associated sub-steps) can optional include introducing an etchant gas into the reaction chamber during the deposition process (optional sub-step 112). In such examples the etchant gas can be introduced separately from the precursor gas composition or alternative with the precursor gas composition. In such examples the etchant gas can comprise a chlorine containing gas, such as, molecular chlorine (Cl₂), for example.

In accordance with examples of the disclosure, sub-step 106, sub-step 108, and sub-step 110 (of method 100) can be performed in parallel, or at least partially in parallel. In other words, the silicon precursor, the germanium halide precursor, and the boron halide dopant precursor can be introduced into reaction chamber together or at least with some overlap in the time of injection (i.e., temporal overlap) of the silicon precursor, the germanium halide precursor, and the boron halide dopant precursor into the reaction chamber. In such examples the parallel, or at least partial parallel, introduction of the silicon precursor, the germanium halide precursor, and the boron halide dopant precursor into the reaction can be referred to herein as the “co-flow” of the precursors (e.g., the constituent precursors of the precursor gas composition) into the reaction chamber.

In alternative examples of the disclosure, sub-step 106, sub-step 108, and sub-step 110 can be performed in a sequence without any substantial overlap between each process step. In such embodiments, the sub-step 106, sub-step 108, and sub-step 110 can be performed in any order and can include repeatedly performing one or more of the sub-steps (106, 108, and 110). In other embodiments, sub-step 106, sub-step 108, and sub-step 110 can be performed as part of a repeating deposition cycle (i.e., a cyclical deposition process) and in such examples, one or more additional steps can be added to the deposition cycle, such as the optional sub-step 112 of introducing an etchant gas into the reaction chamber. In some embodiments a single deposition cycle can comprise the introduction of the silicon precursor (sub-step 106), the introduction of the germanium halide precursor (sub-step 108), and the introduction of the boron halide dopant precursor (sub-step 110) into the reaction chamber, and the single deposition may be repeated one or more times in order to deposit a boron doped silicon germanium layer with the desired thickness and composition. In further examples a single deposition cycle can comprise the introduction of the silicon precursor (sub-step 106), the introduction of the germanium halide precursor (sub-step 108), the introduction of the boron halide dopant precursor (sub-step 110), and the introduction of the etchant gas into the reaction chamber (optional sub-step 112), and the single deposition cycle may be repeated one or more times in order to deposition a boron doped silicon germanium layer with the desired thickness and composition. In such further examples that incorporate the etchant gas during the deposition of the SiGe:B layer the deposition process may comprise a cyclical deposition-etch process, such as a selective epitaxial cyclical deposition-etch process, for example. Further in such cyclical deposition processes examples, the etchant gas may not be introduced during each and every cycle of the deposition process but rather the etchant gas can be introduced during selected cycles. For example, a cyclical deposition-etch process may comprise introducing the etchant gas (optional sub-step 112) every 2, or 3, or 5, or 10, or 20 cycles.

As described above, the deposition of the boron doped silicon germanium layer can comprise the introduction of a precursor gas composition into the reaction reactor, the precursor gas composition including a silicon precursor component. In one aspect the silicon precursor comprises a single silicon precursor. In another aspect the silicon precursor can comprise two or more silicon precursors, as described below.

In accordance with examples of the disclosure, the silicon precursor can have a general formula of the form SiₙXₘH₂ₙ₊₂₋ₘ, with X being selected from Cl, Br, and I, with n being an integer from at least 2 to at most 4, and with m being an integer from at least 1 to at most 2n+2−m.

In some embodiments X is bromine (Br) and the silicon precursor comprises a bromosilane precursor.

In some embodiments X is iodine and the silicon precursor comprises an iodosilane precursor.

In some embodiments X is chlorine (CI) and the silicon precursor comprises a chlorosilane precursor. In such embodiments the chlorosilane silicon precursor has a general formula of the form SiₙClₘH₂ₙ₊₂₋ₘ, with n being an integer from at least 2 to at most 4, and with m being an integer from at least 1 to at most 2n+2−m. In such embodiments the chlorosilane precursor can comprise at least one of Si₂Cl₅H, Si₂ClH₅, Si₂Cl₂H₄, and Si₃Cl₈. In some embodiments the chlorosilane precursor is and/or comprises Si₂Cl₅H.

In accordance with examples of the disclosure, the silicon precursor can comprise a higher order halosilane precursor. In such examples the halosilane precursor can comprise a chemical compound having a chemical formula including 2 or more silicon atoms and 1 or more halide atoms. For examples, the halosilane precursor may comprise a chlorosilane precursor having a chemical formula including 2 or more silicon atoms and 1 or more chlorine atoms. Not to limited by any theory or process, a higher order chlorosilane precursor can include a weaker Si—Si bond which may provide benefits in the deposition of the boron doped silicon germanium layers of the present disclosure.

In accordance with examples of the disclosure, the silicon precursor can comprise a chlorosilane precursor and one or more additional silicon precursors. In such examples, the precursor gas composition can comprise a chlorosilane and an additional silicon precursor selected from a group consisting of silanes, chlorosilanes, and iodosilanes. For example, the additional silicon precursor can include a hydrogenated silicon precursor. In such examples the hydrogenated silicon precursor can be selected from a group consisting of silane (SiH₄), disilane (Si₂H₆), trisilane (Si₃H₈), and tetrasilane (Si₄H₁₀). In further examples the additional silicon precursor can comprise a silicon halide precursor. In such examples the silicon halide precursor can comprise a silicon chloride precursor selected from a group consisting of monochlorosilane (MCS), dichlorosilane (DCS), trichlorosilane (TCS), hexachlorodisilane (HCDS), octachlorotrisilane (OCTS), and silicon tetrachloride (STC). In further examples the additional silicon precursor can comprise a silicon iodide precursor. In such examples the silicon halide precursor can comprise a silicon iodide precursor selected from a group consisting of monoiodosilane, diiodosilane, triiodosilane, tetraiodosilane. In some embodiments the additional silicon precursor comprises diiodosilane. In some embodiments the additional silicon precursor comprises monoiodosilane.

As described above, the introduction of the precursor gas composition into the reaction reactor can include the introduction of germanium halide precursor as component of the precursor gas composition (e.g., sub-step 108 of method 100). In one aspect the germanium halide precursor comprises a single germanium halide precursor. In another aspect the germanium halide precursor can comprise two or more germanium halide precursor, as described below.

In more detail, sub-step 108 of method 100 (FIG. 1) comprises introducing a germanium halide precursor into the reaction chamber. In accordance with examples of the disclosure, the germanium halide precursor can comprise a germanium chloride precursor. In some embodiments the germanium halide precursor comprises a chloro-germane precursor. In some embodiments the germanium halide precursor comprises at least one of GeCl₃H, GeCl₄, GeClH₃, GeCl₂H₂, and Ge₂ClH₅.

In accordance with examples of the disclosure, introducing the germanium halide precursor (sub-step 108) can comprise the introduction of a germanium halide precursor and an additional germanium precursor into the reaction chamber. For example, the additional germanium halide precursor can comprise one or more of the germanium halide precursor provided above. In some embodiments the precursor gas composition introduced into the reaction chamber for the deposition of the boron doped silicon germanium layer (step 104 and associated sub-step 108) can include one or more of the germanium halide precursors as provided above with the addition of an additional germanium precursor. In some embodiments the additional germanium precursor can comprise a germane, such as germane (GeH₄), digermane (Ge₂H₆), trigermane (Ge₃H₈), or germylsilane (GeH₆Si). In some embodiments the additional germanium precursor can comprise an additional germanium halide such as GeCl₄, GeCl₂, and GeCl₂H₂, for example. In some the two or more germanium precursors are introduced into reaction chamber along with a silicon precursor (sub-step 106) and a boron halide dopant precursor (sub-step 106). In such embodiments the two or more germanium precursors can comprises germane compounds, germanium chloride compounds, or a mixture of both germanes and germanium chloride compounds. In some embodiments the two or germanium precursors are co-flowed into the reaction chamber during sub-step 108.

As described above, the introduction of the precursor gas composition into the reaction reactor can include the introduction of a boron halide dopant precursor as component of the precursor gas composition (e.g., sub-step 110 of method 100). In one aspect the boron halide dopant precursor comprises a single boron halide dopant precursor. In another aspect the boron halide dopant precursor can comprise two or more boron halide dopant precursor, as described below.

In accordance with examples of the disclosure, sub-step 110 of method 100 (FIG. 1) comprises introducing a boron halide dopant precursor into the reaction chamber. In such examples sub-step 110 can comprise introducing a boron halide dopant precursor into the reaction chamber, the boron halide dopant precursor having a general formula of the form BₚY_{q}H_{3p-q}, with Y being selected from Cl, Br, and I, with p being an integer from at least 1, and q being an integer from at least 1 to at most 3p. In some embodiments the boron halide dopant precursor comprises a boron chloride dopant precursor, such as BCl₃, for example. In some embodiments the boron halide dopant precursor comprises a boron bromide dopant precursor, such as BBr₃, for example. In further embodiments the boron halide dopant precursor comprises a halo-borane precursor. In such embodiments the halo-borane precursor can comprise a chloroborane dopant precursor, such as, for example BH₂Cl and BCl₂H.

In accordance with examples of the disclosure two or more boron dopant precursor precursors can be introduced into reaction chamber during sub-step 110 of method 100. In such examples, the two or more boron precursors can comprise the boron halide dopant precursor as described above, with the additional of an additional boron dopant precursor. For example, the additional boron dopant precursor can comprise one or more of the boron halide dopant precursors as previously described above. In further examples, the additional boron dopant precursor(s) may comprise a borane such as, for example, diborane (B₂H₆), or deuterium-diborane (B₂D₆). In such embodiments the two or more boron precursors can comprises boranes, boron chloride compounds, boron bromide compounds or a mixture thereof.

In some embodiments the two or more boron dopant precursors are introduced into reaction chamber along with a silicon precursor (sub-step 106) and a germanium chloride precursor (sub-step 108). In such embodiments the two or more boron dopant precursors can comprises borane compounds, boron halide compounds, or a mixture of both boranes and boron halide compounds. In some embodiments the two or boron dopant precursors are co-flowed into the reaction chamber during sub-step 110.

As described above, the selective epitaxial deposition processes provided for the selective deposition of the boron doped silicon germanium layer can comprise the introduction of a precursor gas composition into the reaction chamber. For example, the selective epitaxial deposition processes provided can comprise heating the substrate to a desired deposition temperature and contacting the substrate with the precursor gas composition.

In accordance with examples of the disclosure, the precursor gas composition can comprise a silicon precursor, a germanium halide precursor, and a boron halide dopant precursor. In such examples the silicon precursor, the germanium halide precursor, and the boron halide dopant precursor are co-flowed into the reaction chamber.

As used herein the term “precursor gas composition” can refer to a gas composition comprising precursor gases that include component elements that are incorporated into the deposited boron doped silicon germanium layer. For example, the boron doped silicon germanium layers of the present disclosure comprises elemental boron, elemental silicon, and elemental germanium, wherein the elemental boron is provided by the boron halide dopant precursor, the elemental silicon is provided by the silicon precursor, and the elemental germanium is provided by the germanium halide precursor.

In accordance with examples of the disclosure, one or more additional gases can be introduced into the reaction chamber along with the precursor gas composition. In such examples, the additional gases may not include component elements that are incorporated into the deposited boron doped silicon germanium layer or are incorporated in an insignificant amount. In such examples the one or more additional gases may comprise a carrier gas and/or a purge gas, such as hydrogen and/or nitrogen, for example. In addition, examples the optional introduction of the etchant gas (e.g., sub-step 110 of method 100) constituents can additionally gas and not a component of the precursor gas composition.

In accordance with examples of the disclosure, the precursor gas composition can comprise a silicon precursor, a germanium halide precursor, and a boron halide dopant precursor, as described above. In some embodiments the precursor gas composition consists essentially of the silicon precursor, the germanium halide precursor, and the boron halide dopant precursor. In some embodiments the precursor gas composition consists of the silicon precursor, the germanium halide precursor, and the boron halide dopant precursor.

In accordance with examples of the disclosure, the precursor gas composition can comprise the silicon precursor, the germanium halide precursor, the boron halide dopant precursor, and one or more additional precursors, such as, for example, at least of an additional silicon precursor, an addition germanium precursor, and an additional boron precursor. In some embodiments the precursor gas composition consists essentially of the silicon precursor, the germanium halide precursor, the boron halide dopant precursor, and one or more additional precursors, such as, for example, at least of an additional silicon precursor, an addition germanium precursor, and an additional boron precursor. In some embodiments the precursor gas composition consists of the silicon precursor, the germanium halide precursor, the boron halide dopant precursor, and one or more additional precursors, such as, for example, at least of an additional silicon precursor, an addition germanium precursor, and an additional boron precursor.

As a non-limiting example, the precursor gas composition can consist essentially of Si₂Cl₅H, GeCl₄, and BCl₃. As a further non-limiting example, the precursor gas composition can consist of Si₂Cl₅H, GeCl₄, and BCl₃.

As an additional non-limiting example, the precursor gas composition can consist essentially of Si₂Cl₅H, GeCl₄, and BBr₃. As a further additional non-limiting example, the precursor gas composition can consist of Si₂Cl₅H, GeCl₄, and BBr₃.

The various embodiments of the disclosure provide methods for selectively depositing boron doped silicon germanium layers. In accordance with examples of the disclosure, the selective deposition processes provided can comprise selective chemical vapor deposition processes. In some embodiments the selective deposition process comprises selective epitaxial deposition processes. In such examples the selective epitaxial deposition process selectively (i.e., preferentially) deposits a boron doped silicon germanium layer on a first surface (surface A) relative to a second surface (surface B).

The skilled artisan will appreciate that selective deposition can be fully selective or partially selective. A partially selective process can result in fully selective layer by a post-deposition etch that removes all of the deposited material from over surface B without removing the entirety of the deposited material from over surface A. Because an etch back process can leave a fully selective structure without the need for expensive masking processes, the selective deposition need not be fully selective in order to obtain the desired benefits. For example, method 100 of FIG. 1 can further comprise an additional optional step 114 which comprises introducing an etchant into the reaction chamber. In such examples, the etchant is introduced into the reaction chamber after completion of the deposition of the boron doped silicon germanium layer (e.g., by performing step 114 upon completion of deposition step 104).

In such examples, introducing the etchant gas into the reaction chamber post-deposition can etch-back any unwanted boron doped silicon germanium layers thereby improving the selectivity of the deposition process. In such examples, the etchant gas may comprise a chlorine containing gas, such as, chlorine (Cl₂), for example.

In further embodiments method 100 may comprise a cyclical deposition-etch process, as previously described above. In such embodiments the steps of depositing the boron halide dopant precursor (e.g., step 104) and introducing the etchant into the reaction chamber (e.g., step 114) can be repeated multiple times in a cyclical manner. In such examples, the etchant gas introduced during optional sub-step 112 sub-step may comprise a chlorine containing gas, such as, chlorine (Cl₂), for example.

The selectivity of the deposition process on surface A relative to surface B can be given as a percentage calculated by [(deposition on surface A)−(deposition on surface B)]/(deposition on the surface A). Deposition can be measured in any of a variety of ways. For example, deposition may be given as the measured thickness of the deposited material, or may be given as the measured amount of material deposited. In some embodiments, the selectivity of the selective deposition of the boron doped silicon germanium layer on surface A relative to surface B is greater than 10%, greater than 50%, greater than 75%, greater than 85%, greater than 90%, greater than 93%, greater than 95%, greater than 98%, greater than 99%, greater than 99.5%, equal to about 100%.

In accordance with examples of the disclosure, the selective deposition processes of the present disclosure enable the selective deposition of a boron doped silicon germanium layer preferentially on a semiconductor surface (surface A) relative to a dielectric surface (surface B).

In such examples, the semiconductor surface (surface A) can include a silicon surface, or a silicon germanium surface and the dielectric surface (surface B) can include a silicon nitride surface and/or a silicon oxide surface. In such examples the boron doped silicon germanium layer is selectively deposited on surface A relative to surface B with a selectivity greater than 10%, greater than 50%, greater than 75%, greater than 85%, greater than 90%, greater than 93%, greater than 95%, greater than 98%, greater than 99%, greater than 99.5%, equal to about 100%.

In accordance with additional examples of the disclosure, the selective deposition processes of the present disclosure enable the selective deposition of a boron doped silicon germanium layer on a first dielectric surface (surface A) relative to a second dielectric surface (surface B). In such examples, the first dielectric surface (surface A) comprises a silicon nitride surface and the second dielectric surface (surface B) can comprise a silicon oxide surface. In such examples, the boron doped silicon germanium layer is selectively deposited (i.e., preferentially) on surface A relative to surface B with a selectivity greater than 10%, greater than 50%, greater than 75%, greater than 85%, greater than 90%, greater than 93%, greater than 95%, greater than 98%, greater than 99%, greater than 99.5%, equal to about 100%.

Various embodiments of the present disclosure also relate to the boron doped silicon germanium layers deposited by the methods described above.

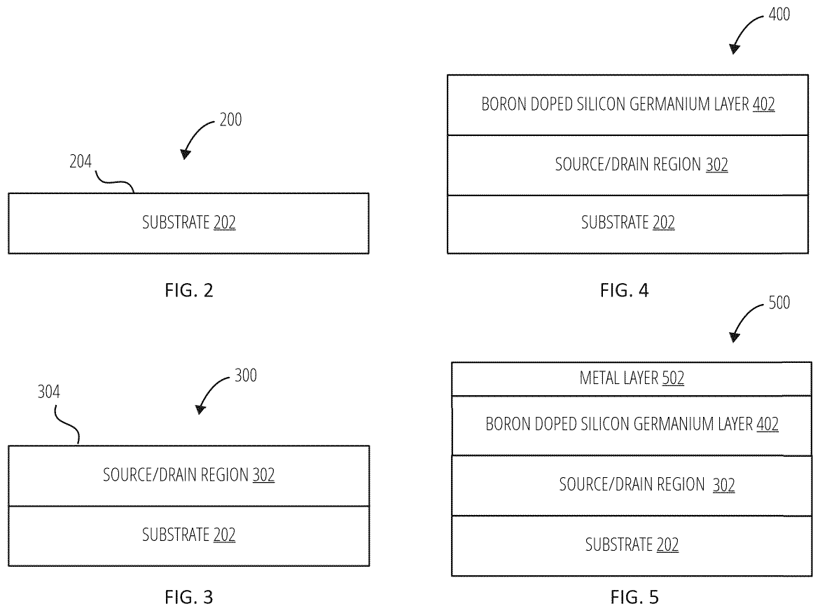

In accordance with examples of the disclosure, FIG. 2 illustrates a structure 200 which comprises a substrate 202 including a surface 204. In some embodiments the boron doped silicon germanium layers of the present disclosure are deposited directly on the surface 204 of the substrate 202. As a non-limiting example surface 204 can include one or more of silicon, silicon germanium, silicon oxide, and silicon nitride.

In accordance with further examples of the disclosure, FIG. 3 illustrates a structure 300 which includes the substrate 202 and a source/drain region 302 of a device structure. In such examples the source/drain region 302 can comprise a silicon germanium source/drain region including one or more layers of silicon germanium of various compositions, thicknesses, and doping concentrations. In such examples the source/drain region 302 includes a surface 304.

Further in such examples the surface 304 can comprise a silicon germanium surface. In other examples the surface 304 includes one or more of a silicon surface, a silicon oxide surface, a silicon nitride surface, and a silicon germanium surface.

In accordance with further examples of the disclosure, FIG. 4 illustrates a structure 400 which includes the previously described substrate 202 and source/drain region 302. In such examples the structure 400 can include a boron doped silicon germanium layers 402 deposited by the methods provided. In some embodiments the boron doped silicon germanium layer 402 is epitaxially deposited directly on the surface 304 of the source/drain region 302. In some embodiments the boron doped silicon germanium layer 402 has a different composition and/or lattice constant to the underlying source/drain region 302. In some embodiments the boron doped silicon germanium layer 402 has a first germanium concentration and the source/drain region 302 comprises a silicon germanium layer having a second germanium concentration different to the first germanium concentration. In some embodiments the boron doped silicon germanium layer 402 is lattice matched to the underlying source/drain region 302. In some embodiments the boron doped silicon germanium layer 402 is fully strained to the underlying source/drain region 302 and is substantially free of misfit type dislocations.

In accordance with examples of the disclosure, the boron doped silicon germanium layer 402 deposited by the methods described above can have an average layer thickness of less than 20 nm, less than 15 nm, less than 10 nm, less than 7 nm, or less than 5 nm. In some embodiments, the boron doped silicon germanium layer 402 has an average layer thickness between 5 nm and 20 nm.

In accordance with examples of the disclosure, the boron doped silicon germanium layer 402 deposited by the methods described above has a high boron dopant concentration and a resulting high active dopant concentration. In such examples the boron doped silicon germanium layer 402 has an active dopant concentration greater than 2.0×10²¹ cm⁻³, greater than 2.5×10²¹ cm⁻³, greater than 3.0×10²¹ cm⁻³, greater than 3.5×10²¹ cm⁻³, greater than 4.0×10²¹ cm⁻³, greater than 4.5×10²¹ cm⁻³, or greater than 5.0×10²¹ cm⁻³. In such examples the boron doped silicon germanium layer 402 also has a high germanium content. For example, the boron doped silicon germanium layer 402 can have a germanium concentration (atomic-%) greater than 40 atomic-%, greater than 50 atomic-%, greater than 55 atomic-%, greater than 60 atomic-%, greater than 65 atomic-%, greater than 70 atomic-%, greater than 75 atomic-%, greater than 80 atomic-%, greater than 85 atomic-%, or greater than 90 atomic-%.

In accordance with further examples of the disclosure, FIG. 5 illustrates a structure 500 which includes the previously described substrate 202, source/drain region 302, and the boron doped silicon germanium layer 402. Structure 500 in additional includes a metal layer 502 formed on (or directly on) the boron doped silicon germanium layer 402. In such examples the boron doped silicon germanium layer 402 comprises a contact layer and the metal layer 502 comprises an electrode for providing electrical contact to the boron doped silicon germanium layer 402 (and underlying layers). In some embodiments structure 500 comprises a portion of a transistor device structure, such as, for example, a gate-all-around device structure, a nanosheet device structure, a forksheet device structure, and a complementary FET (CFET) device structure.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of selectively depositing a boron doped silicon germanium layer on a substrate disposed within a reaction chamber, the method comprising:
heating the substrate to a deposition temperature; and
depositing the boron doped silicon germanium layer on a surface of the substrate by a selective epitaxial deposition process comprising:
introducing a silicon precursor into the reaction chamber, the silicon precursor having a general formula of the form SiₙXₘH₂ₙ₊₂₋ₘ, with X being selected from Cl, Br, and I, with n being an integer from at least 2 to at most 4, and with m being an integer from at least 1 to at most 2n+2−m;
introducing a germanium halide precursor into the reaction chamber; and
introducing a boron halide dopant precursor into the reaction chamber, the boron halide dopant precursor having a general formula of the form BₚY_{q}H_{3p-q}, with Y being selected from Cl, Br, and I, with p being an integer from at least 1, and q being an integer from at least 1 to at most 3p.

2. The method of claim 1, wherein the silicon precursor, the germanium halide precursor, and the boron halide dopant precursor are co-flowed into the reaction chamber.

3. The method of claim 2, wherein the deposition temperature is between 250° C. and 450° C.

4. The method of claim 3, wherein the silicon precursor comprises a chlorosilane precursor selected from a group consisting of Si₂Cl₅H, Si₂ClH₅, Si₂Cl₂H₄, and Si₃Cl₈.

5. The method of claim 4, wherein the chlorosilane precursor comprises Si₂Cl₅H.

6. The method of claim 3, wherein the germanium halide precursor comprises a germanium chloride precursor.

7. The method of claim 6, wherein the germanium chloride precursor comprises at least one of GeCl₃H, GeCl₄, GeClH₃, GeCl₂H₂, and Ge₂ClH₅.

8. The method of claim 3, wherein the boron halide dopant precursor comprises at least one of BH₂Cl, BCl₂H, BCl₃, and BBr₃.

9. The method of claim 3, wherein the selective epitaxial deposition process deposits the boron doped silicon germanium layer on a surface A relative to a surface B, wherein the surface A is a semiconductor surface, and the surface B is a dielectric surface.

10. The method of claim 9, further comprising introducing an etchant into the reaction chamber.

11. A method of forming a boron doped silicon germanium layer on a substrate, the method comprising:
heating the substrate to a deposition temperature 250° C. and 450° C.; and
contacting the substrate with a precursor gas composition, the precursor gas composition comprising:
a silicon precursor having a general formula of the form SiₙClₘH₂ₙ₊₂₋ₘ, with n being an integer from at least 2 to at most 4, and with m being an integer from at least 1 to at most 2n+2−m;
a germanium halide precursor comprising one or more of GeCl₃H, GeCl₄, GeClH₃, GeCl₂H₂, and Ge₂ClH₅; and
a boron halide dopant precursor comprising one or more of BCl₃ and BBr₃.

12. The method of claim 11, wherein the precursor gas composition consists essentially of the silicon precursor, the germanium halide precursor, and the boron halide dopant precursor.

13. The method of claim 12, wherein the silicon precursor comprises one or more of Si₂Cl₅H, Si₂ClH₅, Si₂Cl₂H₄, and Si₃Cl₈.

14. The method of claim 13, wherein the boron doped silicon germanium layer is formed by a selective epitaxial deposition process which preferentially deposits the boron doped silicon germanium layer on a surface A relative to a surface B, wherein the surface A is a silicon surface or silicon germanium surface, and the surface B is a silicon oxide surface or a silicon nitride surface.

15. The method of claim 11, wherein the precursor gas composition further comprises an additional germanium precursor selected from a group consisting of GeH₄, Ge₂H₆, Ge₃H₈, GeH₆Si, GeCl₄, GeCl₂, and GeCl₂H₂.

16. The method of claim 11, wherein the precursor gas composition further comprises an additional silicon precursor selected from a group consisting of silanes, chlorosilanes, and iodosilanes.

17. The method of claim 11, wherein the precursor gas composition further comprises an additional boron precursor selected from a group consisting of B₂H₆, B₂D₆, BH₂Cl, BCl₂H, BCl₃, and BBr₃.

18. A method of forming a contact layer to a silicon germanium source/drain region, the method comprising:
seating a substrate within a reaction chamber, the substrate comprising one or more silicon germanium source/drain regions;
heating the substrate to a deposition temperature between 250° C. and 450° C.; and
depositing a boron doped silicon germanium layer directly on a surface of the silicon germanium source/drain region by a selective epitaxial deposition process by co-flowing into the reaction chamber a precursor gas composition comprising:
a silicon precursor having a general formula of the form SiₙXₘH₂ₙ₊₂₋ₘ, with X being selected from Cl, Br, and I, with n being an integer from at least 2 to at most 4, and with m being an integer from at least 1 to at most 2n+2−m;
a germanium halide precursor; and
a boron halide dopant precursor having a general formula of the form BₚY_{q}H_{3p-q}, with Y being selected from Cl, Br, and I, with p being an integer from at least 1, and q being an integer from at least 1 to at most 3p.

19. The method of claim 18, wherein the selective epitaxial deposition process deposits the boron doped silicon germanium layer on the surface of the silicon germanium source/drain region relative to a silicon oxide surface or a silicon nitride surface.

20. The method of claim 18 wherein the deposited boron doped silicon germanium layer has both an active dopant concentration greater than 2×10²¹ cm⁻³ and a germanium content greater than 40 atomic percent (atomic-%).
